(19) United States
(12) Patent Application Publication
(10) Pub. No.: US 2014/0197887 A1
(43) Pub. Date: Jul. 17, 2014

(54) Telescopic OP-AMP With Slew Rate Control

(71) Applicant: Knowles Electronics, LLC, Itasca, IL (US)

(72) Inventors: Per Flemming Hovesten, Maaloev (DK); Claus Erdmann Furst, Roskilde (DK); Aziz Yurttas, Copenhagen (DK)

(73) Assignee: Knowles Electronics, LLC, Itasca, IL (US)

(21) Appl. No.: 14/154,298

(22) Filed: Jan. 14, 2014

Related U.S. Application Data
(60) Provisional application No. 61/752,538, filed on Jan. 15, 2013.

(51) Int. Cl. H03F 3/26; H03F 3/45

(52) U.S. Cl. CPC H03F 3/265; H03F 3/45179
USPC 330/255

(57) ABSTRACT

An operational amplifier includes a transfer circuit, a cascode control circuit, and a slew rate boost circuit. The transfer circuit is configured to apply a transfer function to a received input signal and the application of the transfer function to the received input signal is effective to create an output signal. The cascode circuit is coupled to the transfer circuit. The cascode circuit is configured to increase an open loop gain of the operational amplifier. The slew rate boost circuit is coupled to the cascode circuit. The slew rate boost circuit is configured to increase the slew rate of the operational amplifier without necessarily increasing the power consumption of the operational amplifier.

### CROSS-REFERENCE TO RELATED APPLICATION

This patent claims benefit under 35 U.S.C. §119 (e) to U.S. Provisional application No. 61/752538, filed Jan. 15, 2013 and entitled “Telescopic Op-amp with Slew rate Control,” the contents of which are incorporated herein by reference in their entirety.

### TECHNICAL FIELD

This application relates to sigma delta modulators and the components used within these modulators

### BACKGROUND OF THE INVENTION

Digital microphones need to convert the analog input from the membrane (e.g., a MEMS device) into a digital bit stream, and here the choice of converter is in almost all cases a sigma delta converter. The restrictions on digital microphones used for mobile telecommunication and hearing instruments are very demanding in respect to signal to noise ratio (SNR), power consumption, voltage supply levels, and power supply rejection (PSR).

It is advantageous to employ a very efficient sigma delta converter, which has very low noise, and uses sub milliwatt power, and that can run on low supply voltages, e.g., approximately 0.8V-1.5V. The particular design of the op amps in a sigma delta modulator is important to the performance of the complete sigma delta modulator, e.g., maintaining adequate signal to noise ratios, power consumptions, THD, and ability to operate at very low supply voltages. This is especially true for the op amp that is used in the first integrator in such devices.

Previous attempts have been made to deploy op amps with these properties, both differential and non-differential systems, and with different types of op amps used in the integrators. Non-differential systems are sensitive to noise injections, and have poorer PSR, but can be made current efficient, especially when an inverter type of op amp is used in the integrators. The differential systems are more robust, but usually consume more power, due to the more complex op amp structure. In all cases, however, previous systems have provided less efficient solutions.

### BRIEF DESCRIPTION OF THE DRAWINGS

For a more complete understanding of the disclosure, reference should be made to the following detailed description and accompanying drawings wherein:

FIG. 1 comprises a circuit diagram of an operational amplifier (op amp) according to various embodiments of the present invention;

FIG. 2 comprises a circuit diagram of a voltage controller for use with the op amp of FIG. 1 according to various embodiments of the present invention;

FIG. 3 comprises a circuit diagram of an integrator using the op amp of FIG. 1 utilized, for example, in a sigma delta modulator according to various embodiments of the present invention;

FIG. 4 comprises a circuit diagram of a common mode feedback network according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

In the approaches described herein, an integrator operational amplifier (op amp), is provided that is differential, but at the same time power efficient and with low noise and able to operate at low supply voltage, e.g., 0.8V-1.5 V. It will be appreciate that generally speaking the most efficient type of op amp is a single stage class-AB op amp, i.e., it is single pole which has lower current consumption for a given bandwidth and settling time. Furthermore, for switched circuits, such as in switch capacitor circuits, the Class AB operation assures that no slewing occurs which would increase the quiescent current needs.

The approaches described herein use a telescopic op amp, because of the single stage nature of this op amp and its differential configuration. The same is true for a differential pair without the cascode transistors applied. The telescopic op amp has, because of the cascade transistors a higher (30-40 dB) higher open loop gain. This is, in particular, an advantage when the op amp is used as an integrator in a sigma delta modulator. The telescopic amplifier is not the obvious choice for low voltage operation, but the approaches described herein accomplishes this by careful control of the DC bias voltages, in particular, controlling the input bias voltage independently of the output bias voltage. These principles can also be used with great benefit for a simple differential pair op amp. But, for a telescopic op amp they are absolutely mandatory.

Consequently, the op amp is configured to be operational over temperature and processes with the ability to handle a maximum output voltage swing. This will assure the best THD performance for the op amp which for sigma delta modulators is a key parametric for achieving a large danamic range (DNR), e.g., non-linearities in the op amps will lead to intermodulation products of the noise shaped quantization noise. These intermodulation products will end up in the audio band and thus increase the noise and lower the DNR of the modulator. The telescopic op amp described herein furthermore is a current efficient implementation, especially compared to previous folded casode op amps, which are often used in differential implementations.

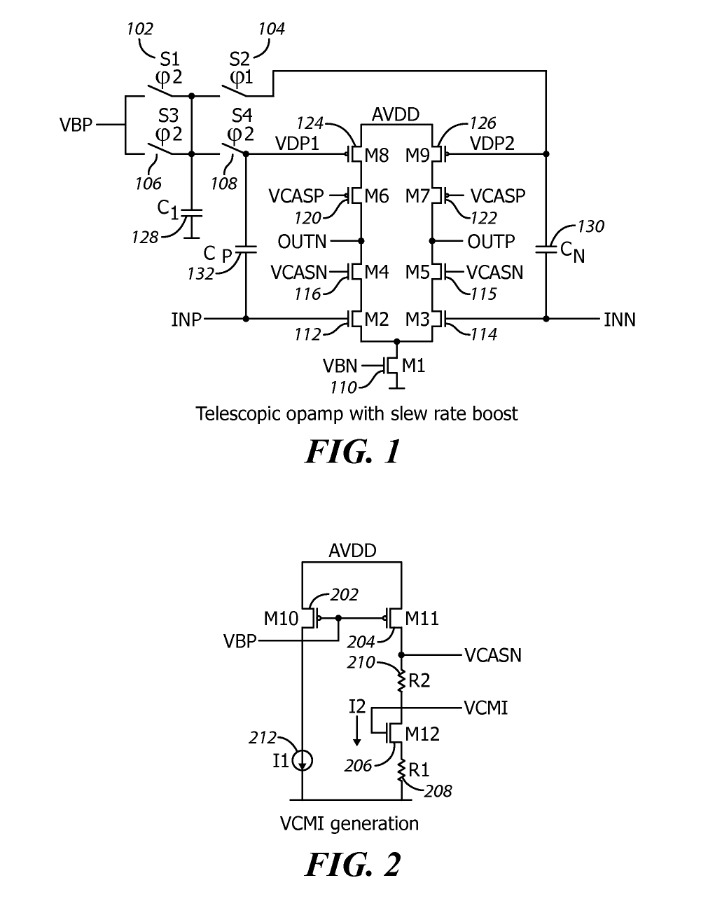

In order to boost the slew rate, the input signal is coupled (via Cp, Cn) to the gates of M8 and M9, allowing these to deliver more current, when needed (see FIG. 1). Normally the current in these transistors (M8, M9) would be fixed, and thus limit the slew rate. Slew rate limitation is problematic when the op amp is used in a sigma delta modulator. Slew rate limitations in the op amp will lead to nonlinear settling which will have the same effect as distortion, i.e., increasing the audio band noise and decreasing the DNR of the modulator.

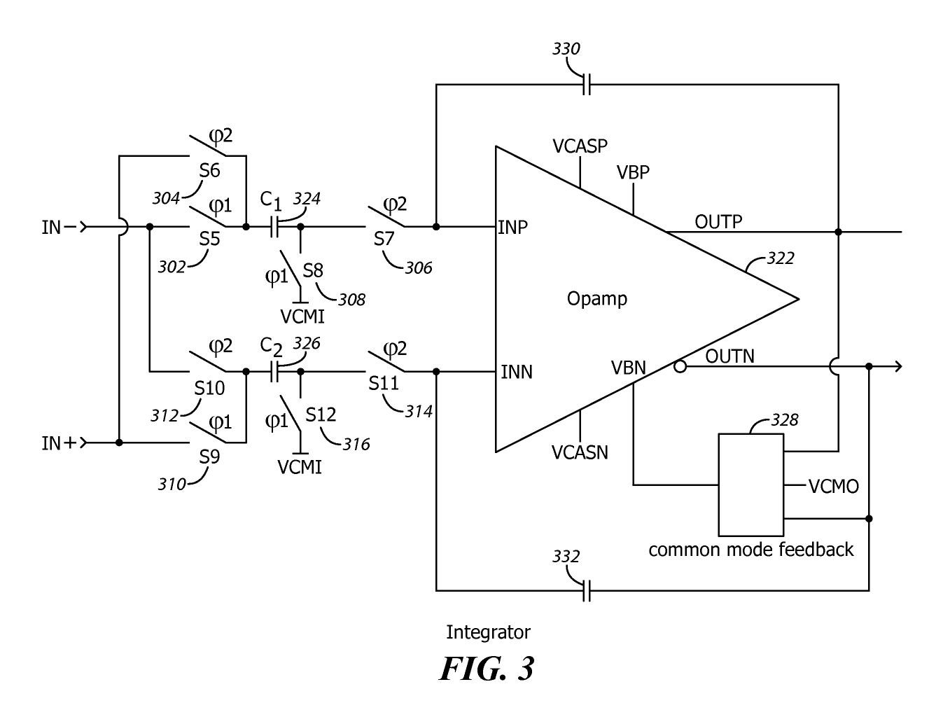

In other aspects, the present approaches utilize a differential op amp in a differential low voltage sigma delta converter using double sampling as shown in FIG. 3. The double sampling implemented by the capacitors C1, C2 and the connected switches. Double sampling effectively doubles the input signal and thus increases the achievable SNR by approximately 3 dB for a given current. This can also be used to lower the current consumption if a given SNR is required. Double sampling combined with a differential structure gives the best possible SNR.

In other aspects, the present approaches utilize a telescopic op amp in a differential low voltage sigma delta converter. The present approaches also set the DC input common mode Voltage (V(CMI)) for making the op amp operation possible at low voltage in process and temperature corners of operation. In other aspects, the use of slew rate boosting is also advantageously used.

Referring now to FIG. 1, the slew rate burst circuit includes a plurality of switches 102 (S1), 104 (S2), 106 (S3), and 108 (S4). By “slew rate,” we mean the rate the output voltage can change within a given time (dV/dt). Here it is determined by the maximum current that the op amp can source or sink. Still referring to FIG. 1, the circuit includes a first transistor 110 (M1), a second transistor 112 (M2), a third transistor 114 (M3), a fourth transistor 116 (M4), a fifth transistor 118 (M5), a sixth transistor 120 (M6), a seventh transistor 122 (M7), an eighth transistor 124 (M8), and a ninth transistor 126 (M9).

The slew rate boost is accomplished by forcing the transistors 112 (M2) and 124 (M8) (and 114 (M3) and 126 (M9)) to work in a push-pull configuration, where the 124 (M8) gate voltage is modulated by the input (INP), so that it can deliver more current to the output, than it would otherwise be able to (when transistor 124 (M8) functions as a constant current source). A capacitor 130 (CN) (and a capacitor 132 (CP)) can be regarded as constant voltage sources with a voltage of V(BP)-V(INP).

The slew rate boost also includes a capacitor 128 (C 1). The purpose of C1 is to transfer charge to capacitor 130 (CN) (and capacitor 132 (CP)) to bias V(BP2) (V(BP1)) to V(BP). This is achieved by clocking the switches 102 (S1) and 104 (S2) by two non-overlapping clocks φ1 and φ2. This effectively makes the system consisting of S1-S2 and capacitor 128 (C1) work as a (switch cap) resistor.

The slew rate booster operates as follows. When switches 102 and 106 (S1 and S3) are closed, this charges the capacitor 128 (C1) to the voltage of V(BP). When switches 104 and 108 (S2 and S4) are closed this transfer charges between the capacitors 128, 130, and 132 (C1 and CN and CP), so that over time (many clock cycles) the voltage at the V(BP), V(BP1) and V(BP2) node will be identical in clock phase φ1, where the V(INN) and V(INP) in the integrator system (See FIG. 3 below) is settled to (identical to) the V(CMI) voltage. By charging these capacitors, the slew rate is increased because the transistors 112 (M2) and 124 (M8) (114 (M3) and 126 (M9)) work in a push-pull configuration in clock phase φ1, where the M8 gate voltage is modulated by the input (INP), so that it can deliver more current to the output, than it would otherwise be able to (when M8 functioning as a constant current source). Increasing the slew rate is beneficial because it decreases the settling time, and settling error of the integrator system. Slew rate boosting is particularly beneficial, because it increases the slew rate without increasing the overall power consumption in the op amp, which would otherwise be necessary to obtain a similar slew rate. As mentioned, the switches 102, 104, 106, and 108 are controlled by 2 non-overlapping clocks φ1 and φ2.

As mentioned, the transistors 124 and 126 (M8 and M9) are controlled by bias voltage V(BP1) and V(BP2), which works together with the transistors 110 and 112 (M1 and M2) as part of a differential push-pull stage. V(BP1) is following the input voltage V(INP), but voltage shifted (VBP-V(INP)) through CP, and is therefore AC-wise controlled by V(INP). The steady state voltage at V(BP1) and V(BP2) is set by VBP through the switch capacitor-resistor circuit (switches 102-108 S1-S4, and capacitor 128 (C1)) as described above.

Transistors 120 and 122 (M6 and M7) are controlled by the voltage V(CASP). V(CASP) is a constant voltage which will make 120 and 122 (M6 and M7) work as cascodes for M8 and M9. The function of these transistors is to increase the open loop gain of the op amp. The op amp gain set by the input transistors 112 and 114 (M2 and M3) gate-channel transconductance (gm) times the output impedance, and since the cascade transistors increase the output impedance, it will effectively also increase the gain. The op amp gain is needed for making the integrator (see FIG. 3 below) settling error small.

Transistors 116 and 118 (M4 and M5) are controlled by the voltage V(CASN). V(CASN) can be generated by the circuit of FIG. 2. The function of these transistors is to work as cascodes for transistors 112 and 114 (M2 and M3). The function and purpose of the transistors 116 and 118 (M4 and M5) are the same as for the transistors 120 and 122 (M6 and M7), that is to increase the op amp open loop gain, which is needed for a practical implementation.

Transistors 112 and 114 (M2 and M3) are controlled by INP and INN, which are the op amp inputs. The function of the transistors 112 and 114 (M2 and M3) is to implement the op amp transfer function, which is to amplify the differential input signal seen at the inputs (INP and INN) to the op amp output (OUTP and OUTN). The differential input signal amplified by the gate-channel transconductance (gm) times the op amp output impedance implements the op amp open loop gain.

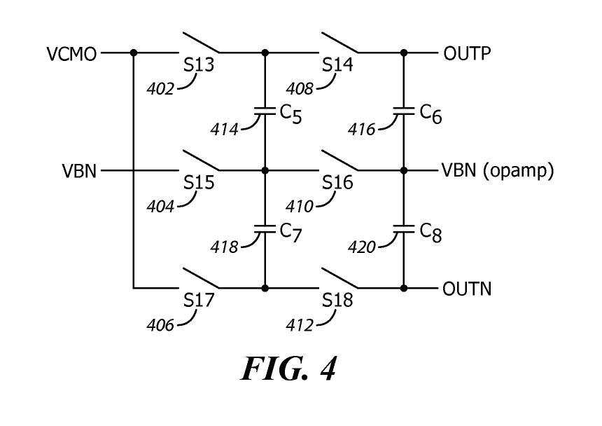

The transistor 110 (M1) is controlled by V(BN). The function of M1 is to provide a voltage controlled current source, which is controlled by a common mode feedback circuit. FIG. 4 (below) is an example of such a circuit. The purpose of the common mode feedback circuit is to control transistor 110 (M1) in such a way the output common mode level is V(CMO), which we set independently from the input common mode level. Typically V(CMO) is set to half the supply voltage in order to be able to achieve a maximum output swing of the op amp.

The voltage across V(BN) is tightly controlled in the application by V(CMI). The reason for this tight control is that the voltage across the transistor 110 (M1) is to provide maximum op amp output swing. In order to be able to achieve a maximum output swing and having the op amp fully functional at low voltages, despite of silicon process variations, and over a wide temperature range, the voltage across the transistor 110 (M1) should be kept to a minimum, but still at a level where the transistor 110 (Ml) is operating as a decent current source. A level of 100 mV 200 mV across the transistor 110 (M1) will typically be sufficient to maintain a correct operation of M1. The voltage at M1's drain (across M1) is set by the voltage at INP and INN, since M2's (M3's) gate-source voltage (Vgs) is constant and approximately one threshold voltage. The steady state DC voltage level at the inputs INP and INN is V(CMI).

Consequently, a telescopic op amp with slew rate boost is shown in FIG. 1. The cascodes transistors (M4-7) are used to achieve sufficient gain. The capacitors and switches implement the slew rate boost, which works in clock phase 2 (φ2), by increasing the source current in the branch that needs it, and decreasing it in the one that does not.

The steady state DC voltage at the op amp V(BP1,2) is V(BP), but at the same time the voltage across the capacitors 130 and 132 (Cp and Cn) is constant. Since the input signal will also be seen on the gate of the transistors 124 and 126 (M8 and M9) through the capacitors 132 and 130 (Cp and Cn), these devices will help drive the output more actively, than just simple current sources, as would otherwise be the case. The value of the capacitor 128 (C1) in one aspect is kept small, but the values of the capacitors 130 and 132 (Cp and Cn) typically should be larger than the gate capacitances of the transistors 112 and 124 (M2, M8) and 114 and 126 (M3, M9) for the slew rate boosting to have an effect.

In one example of the operation of the network of FIG. 1, signals (INP and INN) or (V(CMI) or V(CMO)) are received. φ1 and φ2 are non-overlapping clocks. The V(CMI) and V(CMO) signals may also be created by the circuit of FIG. 2. The V(CMI) signal maintains a generally constant voltage across M1.

Referring now to FIG. 2, one example of V(CMI) generation is described. The circuit has a first transistor 202 (M10), a second transistor 204 (M11), a resistor 210 (R2), a transistor 206 (M12), a current source 212 (I1), and a resistor 208 (R1).

FIG. 2 illustrates how to generate the DC operation voltages for the op amp. Current source 212 (I1) is a current source, which tracks the resistors 208 and 210 (R1 and R2).

Resistor 208 (R1) fixes the voltage across the bottom current source (See transistor 110 (M1) in FIG. 1). M1 should somehow be matched to the input transistors in the op amp (See transistors 112 and 114 (M2 and M3 in FIG. 1)), and defines a DC input voltage (V(CMI)), where the op amp works well. The cascode voltage (V(CASN)) can easily be generated as a fixed voltage above V(CMI) by the resistor 210 (R2). The generation of V(CASP) is not shown, but can be generated in a traditional way as known to those skilled in the art.

The function of the transistors 202 and 204 (M10 and M11) is to provide a current mirror, which mirrors the current through transistors 202 and 204 (M10 to M11). That is to say at the current through transistors 202 and 204 (M10 and M11) is the same, if the transistors 202 and 204 (M10 and M11) are similar sized transistors .

The function of the resistor 208 (R1) is to generate the voltage, which we would like to have across M1 (FIG. 1) V=R1*I1. The function of the current source 212 (I1) is to deliver a current. The function of the resistor 210 (R2) is to generate V(CASP), which should be a fixed voltage above V(CMI), e.g., 200 mV. V(CASP)=V(CMI)+R2*I1.

The function of the transistor 206 (M12) is to generate a similar voltage as Vgs for the transistors 112 (M2) and 114 (M3) in FIG. 1. For this reason, the transistor 206 (M12) should be similar (or identical) to the transistors 112 (M2) (and 114 (M3)), and the current flowing through transistor 206 (M12) (12, should in FIG. 2) should be similar to the current flowing through transistor 112 (M2) (I(M2). Scaling of M12 and 12 relative to M2 and I(M2) can be applied.

Setting a constant voltage across the transistor 110 M1 (in FIG. 1) is achieved by generating a constant voltage across R1 (V_{R1}=R1*I2), adding a Vgs of transistor 206 (M12) thereby generating V(CMI), This voltage will also be seen as the steady state voltage on INP and INN, and since voltage across the transistor 110 (M1) (V_{M1}) is V(CMI)−Vgs for the transistor 112 (M2) (transistor 114 (M3)) it will be equal to V_{R1} (Vgs for the transistor 206 (M12), transistor 112 (M2) and the transistor 114 (M3) is equal).

If the current source 212 (I1) is dependent of process changes in resistors 208 and 210 (R1 and R2) the voltage of across these will not change over process and temperature. This is very easily implemented by having I1 derived from a commonly used PTAT circuit as known to those skilled in the art. Since the Vgs of the transistors 206 (M12), 112 (M2), and 114 (M3) will change in same way over process and temperature the voltage across the transistor 110 (M1) will also remain constant.

Referring now to FIG. 3, one example of a circuit using the op amp of FIG. 1 is described. The circuit of FIG. 3 itself may be utilized in a sigma delta modulator. The circuit of FIG. 3 includes an op amp 322, a common mode network 328, switches 302 (S5), 304 (S6), 306 (S7), 308 (S8), 310 (S9), 312 (S10), 314 (S11), and 316 (S12), and capacitors 324 and 326 (C1 and C2). Although used in sigma delta modulators, other uses are also possible.

FIG. 3 shows an example a sigma delta integrator using the telescopic op amp 322. The generation of V(BP), V(CASN), and V(CMI) has already been shown with respect to FIG. 2. V(CMO) is the DC output common mode voltage (typically half supply voltage), and is here different from the DC input common mode voltage, that should be controlled tightly, and be dependent of process and temperature in order for the telescopic op amp to operate. The steady state DC voltage across the feed forward capacitors 324 and 326 (C1, C2) is V(CMO)−V(CMI), which is 0V, if the V(CMI) is the same as the DC output common mode voltage of the previous stage. This will effectively make the input DC voltage at the op amp input V(CMI). The common mode feedback network 328 works on the op amp V(BN) input (see op amp of FIG. 1), and an example of a commonly used implementation is shown in FIG. 4. Capacitors 330 and 332 are provided to implement the integrator function of the circuit. The function of a common mode feed back network 328 is to set the output common mode level to V(CMO).

It will be appreciated that the integrator circuit shown in FIG. 3 operates to integrate signals as known to those skilled in the art and its further operation will not be described in greater detail here.

Referring now to FIG. 4, a common mode feedback network is described. The network includes switches 402, 404, 406, 408, 410, and 412 (S13, S14, S15, S16, S17, and S18); and capacitors 414, 416, 418, and 420 (C5, C6, C7, and C8). Clocking signals control the selective opening and closing of the switches.

Common mode techniques are a well known technique for providing common mode stability for operation of a circuit. There may be two phases of the clock. Generally, the op amp is used during the second phase of the clock. During a first phase of the clock, capacitors are charged to the desired output level of the common mode voltage. The output of the network is connected to the op amp during this phase. During the second phase, the capacitors have been charged and are connected to a node of the op amp. Even though a differential output voltage may exist on the op amp, the average voltage applied to the node is the common mode voltage. The further operation of this circuit will not be described herein since it is already well known to those skilled in the art.

More particularly, the function of the transistor 110 (M1) in FIG. 1 is to provide a voltage controlled current source, which is controlled by a common mode feedback circuit shown in FIG. 4. The purpose of the common mode feedback circuit is to control transistor 110 (M1) in such a way the output common mode level is V(CMO), which we set independently from the input common mode level. Typically V(CMO) is set to half the supply voltage in order to be able to achieve a maximum output swing of the op amp.

Preferred embodiments of this invention are described herein, including the best mode known to the inventors for carrying out the invention. It should be understood that the illustrated embodiments are exemplary only, and should not be taken as limiting the scope of the invention.

What is claimed is:

1. An operational amplifier, comprising:
a transfer circuit, the transfer circuit configured to apply a transfer function to a received input signal and the application of the transfer function to the received input signal being effective to create an output signal;
a cascode circuit coupled to the transfer circuit, the cascode circuit configured to increase an open loop gain of the operational amplifier;
a slew rate boost circuit, the slew rate boost circuit coupled to the cascode circuit, the slew rate boost circuit configured to increase the slew rate of the operational amplifier without necessarily increasing the power consumption of the operational amplifier.

2. The operational amplifier of claim 1 further comprising a common mode control circuit, the common mode control circuit being coupled to the transfer circuit, the common mode control circuit being configured to set an output common mode level independently from an input common mode level.

3. The operational amplifier of claim 2 wherein the common mode control circuit comprises a transistor and wherein a generally constant voltage is maintained across the transistor.

4. The operational amplifier of claim 1 wherein the slew rate boost circuit comprises a plurality of switches, a plurality of transistors, and a plurality of capacitors.

5. The operational amplifier of claim 1 wherein the cascode circuit comprises a plurality of cascode transistors.

6. The operational amplifier of claim 1 wherein the slew rate boost circuit comprises a first transistor and a second transistor that are configured to operate in a push-pull configuration.

7. The operational amplifier of claim 1 wherein the slew rate boost circuit comprises a plurality of switches that are operated by a first clock and a second clock, the first clock and the second clock being non-overlapping in operation.

8. The operational amplifier of claim 1 wherein the operational amplifier is utilized in a sigma delta modulator.

9. The operational amplifier of claim 1 wherein the operational amplifier is utilized in a sigma delta modulator in a microphone.

10. The operational amplifier of claim 1 wherein the operational amplifier has a DC input bias voltage and a DC output bias voltage, the DC input bias voltage and DC output bias voltage being set independently from the other.

11. The operational amplifier of claim 1 wherein the operational amplifier is a single pole operational amplifier.
